(19) United States
(12) Patent Application Publication
(10) Pub. No.: US 2025/0392285 A1
(43) Pub. Date: Dec. 25, 2025

(54) Piezoelectric Microacoustic Metamaterial Filters

(71) Applicant: Northeastern University, Boston, MA (US)

(72) Inventors: Cristian Cassella, Boston, MA (US); Onurcan Kaya, Boston, MA (US)

(21) Appl. No.: 19/246,123

(22) Filed: Jun. 23, 2025

Related U.S. Application Data
(60) Provisional application No. 63/663,027, filed on Jun. 21, 2024.

(51) Int. Cl. H03H 9/54; H03H 3/02

(52) U.S. Cl. CPC H03H 9/542; H03H 3/02

(57) ABSTRACT

Microacoustic metamaterial filters for use in electronic devices are provided. The filters include an acoustic metamaterial transmission line and two acoustic metamaterial reflectors. The filters do not employ resonators and can be easily fabricated. The center frequency of the filter passband, and filter bandwidth is not limited by material properties. The filters can be very small, because stopbands are used to attain large out of band rejection without requiring more filter stages. The filters can be used for 5G or 6G wireless communications, and for other types of electronic filters.

### CROSS REFERENCE TO RELATED APPLICATIONS

This application claims the priority of U.S. Provisional Application No. 63/663,027 filed 21 Jun. 2024 and entitled “Piezoelectric Microacoustic Metamaterial Filters”, the whole of which is hereby incorporated by reference.

### STATEMENT REGARDING FEDERALLY SPONSORED RESEARCH OR DEVELOPMENT

This invention was made with government support under Grant Number 2103351 awarded by the National Science Foundation. The Government has certain rights in the invention.

### BACKGROUND

Over the last two decades, piezoelectric microacoustic filters have been essential components of commercial radiofrequency (RF) front-ends. These devices typically leverage the piezoelectric excitation of a set of acoustic resonances, electrically or mechanically coupled to generate bandpass filtering characteristics in their electrical frequency response. Due to the acoustic wavelength being orders of magnitude shorter than the electromagnetic one, microacoustic filters offer exceptional degrees of miniaturization [1], [2]. This is crucial for the current chip-scale multiband radios to maintain a compact form factor. Aluminum nitride (AlN) has been the most used piezoelectric material in cellular handsets over the last thirty years. This has been driven by the fact that AlN is low-loss, has a wide bandgap, and can be processed using steps, materials, and temperature conditions available when building Complementary Metal Oxide Semiconductor (CMOS) circuits. Only recently has interest shifted to scandium-doped AlN (AlSCN). AlScN shows higher piezoelectric coefficients than AlN when doped with high scandium-doping concentrations. This enables wider fractional bandwidths in microacoustic filters [3]-[9].

Prior to the present invention, the two main acoustic filter technologies have been: Surface Acoustic Wave (SAW) filters [10], [11], and Bulk Acoustic Wave (BAW) filters [12]-[15]. SAW and BAW filters differ in the acoustic modes they leverage to create their electrical passband. The former relies on the propagation of SAWs, while the latter relies on the propagation of BAWs. SAW and BAW filters are characterized by insertion-loss, bandwidth and frequency selectivity determined by the achievable electromechanical performance of their resonant structures (e.g., by material properties). They are often designed using a “ladder” arrangement, incorporating multiple one-port resonators that are electrically interconnected. These resonators must be designed so that their resonance frequencies adhere to a precise relationship, which is key to ensure proper impedance matching. In practice, this can be a challenging task due to process variations and non-homogeneity in the thickness of the forming layers of these resonators. Post-processing fabrication steps like mass-loading and trimming have made it possible to overcome these challenges when manufacturing BAW ladder filters operating up to a few GHz, at the expense of higher manufacturing costs. Nevertheless, performing these procedures necessitates precise control over the thickness of a tuning layer within the body of these resonators. This task is challenging and becomes even more daunting when dealing with BAW filters operating in the mm-wave range. Such filters generally employ thinner resonators, demanding thickness resolutions that can be as low as a fraction of Angstroms during mass loading or trimming processes [16], [17].

The use of distinct resonators can also introduce large ripples in the group delay within the passband of ladder filters [18]. These ripples affect the radio's capability to accurately decipher information encoded in the phase of a received RF signal. The amplitude of these ripples increases proportionally with the filter order (i.e., coinciding with the number of resonators used) and quality factor (Q) of the resonators employed, while decreasing inversely with the electromechanical coupling coefficient (kt2) of the resonators.

Alternative BAW filters using two-port Lamb wave resonators [19]-[22] or acoustically coupled resonances [23]-[26] have also been reported. Two port Lamb wave resonators usually have narrower bandwidths compared to ladder filters. Also, their out-of-band rejection is worse than that of ladder filters. Acoustically coupled filters, on the other hand, provide wider bandwidths compared to ladder filters. However, their near-band selectivity is worse than that of ladder filters. These effects explain why both two port Lamb wave resonators and acoustically coupled filters have not been considered for use in multiband RF front-ends.

Hybrid filters formed by a set of identical microacoustic resonators coupled through electrical lumped components have also been proposed [18], [27]-[30]. These filters, often referred to as “Acoustic-Wave-Lumped-element-Resonator (AWLR) filters”, can exhibit bandpass characteristics with relatively flat group-delays [18], can be designed to have improved out-of-band isolation [27], or can provide a reconfigurable transfer function [29]. AWLR filters employ replicas of identical microacoustic resonators, interconnected through cascaded networks of inductors and capacitors. Relying on copies of the same resonator relaxes the fabrication complexity with respect to conventional ladder filters using at least two different resonator-types, at the expense of a significantly larger form factor and higher loss. AWLR filters can achieve broader passbands compared to those possible with only microacoustic devices, although their bandwidth is still limited by the kₜ² of the resonators used. Unfortunately, the response of these filters remains sensitive to process variations affecting their microacoustic resonators. Also, their out-of-band rejection per filter-stage is determined by the Q of the adopted lumped components, which typically does not exceed 120 for ceramic components. Consequently, AWLR filters typically necessitate multiple stages, resulting in higher insertion loss and a larger form factor.

Given the limitations of existing microacoustic filter technologies, there is a need to develop high-performance microacoustic filters that do not rely on resonators. However, achieving good out-of-band rejection without using high Q resonators is one of the biggest challenges in developing such desired filter components.

Acoustic metamaterials (AMs) can generate effective material properties that are not readily available in nature, such as negative bulk modulus and/or negative mass density [31]-[33]. This unique feature enables new ways of controlling acoustic waves and paves the way for exotic applications, such as acoustic cloaking [34], [35], vibration isolation for MEMS structures, [36], and imaging [37], [38]. The potential of AMs embodying a piezoelectric layer to enhance the performance of BAW resonators operating in the RF range also has been explored. A new class of RF resonators, namely the Two-Dimensional-Resonant-Rods (2DRR) devices, also has been explored [39], [40]. 2DRRs exploit a set of reactively coupled quasi-thickness modes of vibration. These modes are internally transduced within an AM structure composed of AlN or AlScN rods, deposited atop a platinum, (Pt)/AlN, or Pt/AlScN bilayer. In another study, it was also shown how the same AM structure used by 2DRRs can be used as a frequency-selective anchor. This allows confinement of the acoustic energy within the body of a contour-mode-resonator even when a large anchoring volume is used along the main direction of motion. The use of a large anchoring volume eases the flow of heat generated during the motion into the surrounding substrate, allowing improved power handling capabilities [41].

### SUMMARY

The present technology provides microacoustic metamaterial filters (MMFs) whose bandpass is not generated by electrically or mechanically coupling acoustic resonances, but from the passbands and stopbands of a chain of three acoustic metamaterial (AM) structures. The structures form an AM transmission line (AMTL) that produces the passbands and two AM reflectors (AMRs) that produce the stopbands. Two single metal strips serve as input and output transducers with a wideband frequency response. Since the MMFs do not rely on resonators, they do not require high-resolution trimming or mass-loading steps to accurately tune the resonance frequency difference between various microacoustic resonant devices. Steps required when fabricating microacoustic resonators, such as finely controlling the thickness of a device layer at resolutions that can be as low as a few Angstroms when building GHz filters, can be avoided with the present MMF devices. The acoustic bandwidth of MMFs is mostly determined by geometrical and mechanical parameters of their AM structures. MMFs necessitate external circuit components for impedance matching, in contrast to previous microacoustic filters that often employ circuit components only to eliminate ripples within their passband.

Exemplary MMFs have been designed and constructed from a 400 nm-thick AlScN film using a 30% scandium-doping concentration, and operate in the radiofrequency (RF) range. The performance of the devices was evaluated through Finite Element Modelling (FEM) simulations and measurements of a set of fabricated devices. When matched with ideal circuit components, the built MMFs exhibited filter responses with a center frequency in the Ultra High Frequency range, a fractional bandwidth (FBW) of about 2.54%, a loss of about 4.9 dB, an in-band group delay in the range of 70±25 ns, and a Temperature Coefficient of Frequency (TCF) of about 22.2 ppm/° C.

The technology can be further summarized in the following list of features.
1. A microacoustic metamaterial bandpass filter (MMF) comprising:
   a substrate;
   a first electrode configured as a layer of a first conductive material disposed on the substrate and extending over a cavity portion of the substrate;
   a piezoelectric material layer disposed on the first electrode opposite the substrate and cavity portion of the substrate;
   an acoustic metamaterial transmission line (AMTL), the AMTL comprising a plurality of AMTL rods disposed on the piezoelectric material layer above the cavity portion, the AMTL rods comprising an electrically insulating material and configured as a parallel linear array of the AMTL rods spaced apart by gaps along a longitudinal dimension of the AMTL rods;
   an input transducer comprising a second electrode disposed along a first side of the AMTL;
   an output transducer comprising a third electrode disposed along a second side of the AMTL opposite the first side of the AMTL;
   a first acoustic metamaterial reflector (AMR) having first and second sides, the first side disposed along the input transducer and opposite the first side of the AMTL, the first AMR comprising a plurality of first AMR rods disposed on the piezoelectric material layer above the cavity portion, the first AMR rods comprising an electrically insulating material and configured as a parallel linear array of the first AMR rods spaced apart by gaps along a longitudinal dimension of the first AMR rods; and
   a second AMR having first and second sides, the first side disposed along the output transducer and opposite the second side of the AMTL, the second AMR comprising a plurality of second AMR rods disposed on the piezoelectric material layer above the cavity portion, the second AMR rods comprising or consisting of an electrically insulating material and configured as a parallel array of the second AMR rods spaced apart by gaps along a longitudinal dimension of the second AMR rods.
2. The MMF of feature 1, wherein the AMTL comprises a plurality of unit cells, each unit cell consisting of a single rod, a portion of the piezoelectric layer on which the rod is disposed, and a portion of the first electrode on which the piezoelectric layer is disposed, wherein each unit cell has a pitch p_{AMTL} which extends from a midpoint of the gap on one side of the rod to a midpoint of the gap on the other side of the rod, and optionally wherein p_{AMTL} is constant for all unit cells of the AMTL.
3. The MMF of feature 1 or feature 2, wherein the first AMR comprises a plurality of unit cells, each unit cell consisting of a single rod, a portion of the piezoelectric layer on which the rod is disposed, and a portion of the first electrode on which the piezoelectric layer is disposed, wherein each unit cell has a pitch p_{AMR1} which extends from a midpoint of the gap on one side of the rod to a midpoint of the gap on the other side of the rod, and optionally wherein p_{AMR1} is constant for all unit cells of the first AMR.
4. The MMF of any of the preceding features, wherein the second AMR comprises a plurality of unit cells, each unit cell consisting of a single rod, the piezoelectric layer on which the rod is disposed, and the first electrode on which the piezoelectric layer is disposed, wherein each unit cell has a pitch p_{AMR2} which extends from a midpoint of the gap on one side of the rod to a midpoint of the gap on the other side of the rod, and optionally wherein p_{AMR2} is constant for all unit cells of the second AMR.
5. The MMF of any of features 2-4, wherein for p_{AMTL}, p_{AMR1}, and/or p_{AMR2} the pitch is equal to 1.2 to 5 times a width of the corresponding rod.
6. The MMF of any of features 2-5, wherein the AMTL has a passband having a center frequency, and wherein the passband center frequency is determined by p_{AMTL}.
7. The MMF of any of features 2-6, wherein each of the AMRs has a stopband having a center frequency, and wherein the stopband center frequency of the first AMR is determined by p_{AMR1}, and wherein the stopband center frequency of the second AMR is determined by p_{AMR2}.
8. The MMF of any of the preceding features, wherein applying an input voltage at the first electrode and ground at the second electrode causes transduction of a longitudinal bulk acoustic wave along a width of the AMTL, and wherein the bulk acoustic wave causes an output voltage relative to ground to be produced at the third electrode.
9. The MMF of any of the preceding features, further comprising matching networks at each of the input transducer and the output transducer.
10. The MMF of any of the preceding features, wherein the passband is in the radio frequency range or in the microwave frequency range.
11. The MMF of any of the preceding features, wherein the MMF does not contain any resonators.
12. The MMF of any of the preceding features, wherein the piezoelectric material comprises or consists of scandium-doped aluminum nitride, such as Al_{0.7}Sc_{0.3}N.
13. The MMF of any of the preceding features, wherein the AMTL rods, the first AMR rods, and/or the second AMR rods comprise silicon dioxide.
14. The MMF of any of the preceding features, wherein the substrate comprises or consists of silicon.
15. The MMF of any of the preceding features, wherein the first electrode comprises or consists of platinum and the second and/or third electrodes comprise aluminum.
16. The MMF of any of the preceding features having one or more of a fractional bandwidth of at least about 2.5%, an insertion loss of less than about 5 dB, an in-band group delay in the range of 70±25 ns, and a temperature coefficient of frequency of about 22 ppm/° C.
17. A filter device comprising two or more identical or nonidentical MMFs of any of the preceding features linked in parallel through their input and output terminals.
18. A circuit, chip, or electronic device comprising one or more MMFs of any features 1-16, or comprising one or more filter devices of feature 17.
19. The MMF of any of features 1-16, or the filter device of feature 17, or the circuit, chip, or electronic device of feature 18, which is embodied in an RF front end of a wireless communication device.
20. A method of filtering a radio frequency or microwave frequency signal in an electronic circuit, the method comprising the steps of:
   (a) providing the MMF of any of features 1-16;
   (b) applying said signal at the input terminal of the MMF; and
   (c) receiving a filtered signal at the output terminal of the MMF.
21. A method of fabricating a microacoustic metamaterial filter, the method comprising the steps of:
   (a) providing a planar insulating substrate;
   (b) depositing a layer of conductive material on a surface of the substrate to form a first electrode;
   (c) depositing a layer of piezoelectric material on the first electrode opposite the substrate;
   (d) depositing a layer of insulating material on the layer of piezoelectric material opposite the first electrode;
   (e) patterning the insulating material to form a first linear array of parallel rods separated by gaps and configured as a transmission line, and second and third linear arrays of parallel rods separated by gaps, the second and third linear arrays configured as first and second reflectors, one reflector disposed on each end of the transmission line;
   (e) depositing a layer of conductive material to form second and third electrodes, wherein each of the second and third electrodes lies in a gap between a side of the transmission line and a side of the first or second reflector, the second and third electrodes each deposited onto an exposed portion of the piezoelectric material in said gaps; and
   (f) etching a cavity in the substrate beneath a portion of the first electrode, the cavity underlying the transmission line and first and second reflectors.
22. The method of feature 21, wherein the planar insulating substrate comprises high resistivity silicon; and/or wherein the first electrode comprises platinum; and/or wherein the piezoelectric material comprises scandium-doped aluminum nitride; and/or wherein the rods comprise silicon dioxide; and/or wherein the second and third electrodes comprise aluminum.
23. The method of feature 21 or feature 22, wherein the first electrode has a thickness from about 50 nm to about 350 nm, and/or wherein the piezoelectric material layer has a thickness from about 200 nm to about 2.5 μm, and/or wherein the second and third electrodes have a thickness from about 50 nm to about 300 nm, and/or wherein the cavity has a height from about 40 μm to about 500 μm.

TABLE I
LIST OF ACRONYMS

| Acronym | Definition |
|---|---|
| AlN | Aluminum Nitride |
| AlScN | Scandium Doped Aluminum Nitride |
| AM | Acoustic Metamaterial |
| AMR | Acoustic Metamaterial Reflector |
| AMTL | Acoustic Metamaterial Transmission Lines |
| AWLR | Acoustic-Wave-Lumped-element-Resonator |
| Au | Gold |
| BAW | Bulk Acoustic Wave |
| CMOS | Complementary Metal Oxide Semiconductor |
| CVD | Chemical Vapor Deposition |
| Cₜ | Capacitance of the input/output transducer |
| C_{M N} | Capacitor used in MMF's matching network |
| C^{opt}_{M N} | The required capacitance to ensure proper |
| | matching of MMF's terminal impedance to 50 Ω |
| FBW | Fractional Bandwidth |
| f_{c} | Center Frequency |
| FEM | Finite Element Modelling |
| HR | High Resistivity |
| ICP-RIE | Inductively Coupled Plasma Reactive Ion |
| | Etching |
| kₜ² | Piezoelectric Coupling Coefficient |
| L_{M N} | Inductor used in MMF's matching network |
| L^{opt}_{M N} | The required inductance to ensure proper |
| | matching of MMF's terminal impedance to 50 Ω |
| MMF | Microacoustic Metamaterial Filter |
| MMF^{(PML)} | MMF whose AMRs are replaced with PMLs |
| MMF^{(SF)} | MMF whose AMRs are replaced with stress- |
| | free boundaries |
| p^{AMR} | Unit cell pitch of an Acoustic Metamaterial |
| | Reflector |
| p^{AMTL} | Unit cell pitch of an Acoustic Metamaterial |
| | Transmission Line |
| PML | Perfectly Matched Layer |
| Pt | Platinum |
| Q | Quality Factor |
| RIE | Reactive Ion Etching |
| Rᵢₙ | Real part of MMF's input impedance |
| R_{OoB}(Left) | Average out-of-band rejection on the left/right |
| R_{OoB}(Right) | side of the MMF's passband |
| SAW | Surface Acoustic Wave |
| Sc_{%} | Scandium-doping concentration |
| SEM | Scanning Electron Microscopy |
| SiO₂ | Silicon Oxide |
| TCF | Temperature Coefficient of Frequency |
| VNA | Vector Network Analyzer |
| 2DRR | 2-Dimensional Resonant Rod |

### BRIEF DESCRIPTION OF THE DRAWINGS

FIG. 1 shows a 3-D and cross-sectional view of a microacoustic metamaterial filter (MMF), including an acoustic metamaterial transmission line (AMTL), placed between two acoustic metamaterial reflectors (AMRs), and two transducers, one for the input and one for the output. Both the AMTL and the AMRs are formed by a combination unit cells with different pitches (p_{AMTL} or p_{AMR}). Each unit cell contains a SiO₂ rod atop an Al_{0.7}Sc_{0.3}N/Pt bilayer.

FIGS. 2A-2C show FEM analysis of the AMTL. FIG. 2A shows the S₂₁ response of the AMTL, including 5 passbands (highlighted in green) and 4 stopbands (highlighted in pink). FIG. 2B shows dispersion curves of the AMTL's unit cell assuming Floquet boundary conditions at its two ends. FIG. 2C shows total displacement modeshapes of the AMTL operating within a passband (at 490 MHz) or a stop-band (at 600 MHz).

FIGS. 3A-3C show FEM analysis of an AMR. FIG. 3A shows the S₂₁ response of one AMR, containing 5 passbands (highlighted in green) and 4 stopbands (highlighted in pink). FIG. 3B shows dispersion curves of the unit cell of the AMR when assuming Floquet boundary conditions at its two ends. FIG. 3C shows total displacement modeshapes of the AMR when operating within a pass-band (at 400 MHz) or a stopband (at 490 MHz).

FIGS. 4A-4C show the impact of the required matching networks on performance of MMFs. FIG. 4A shows a circuit schematic depicting the lowest order matching networks that can be used to match the MMFs' input and output transducers to 50Ω. FIG. 4B shows the required inductance (in black) and capacitance (in red) vs. Cₜ to ensure proper matching of the MMF transducers to 50Ω. FIG. 4C shows the ohmic loss caused by the two required matching networks (one per port) for varying Cₜ values, when assuming a Q of 75, 150, or infinity for the matching inductors.

FIG. 5 shows the FEM simulated insertion loss of MMF (black curve), MMF^{PML} (red curve) and MMF^{SF} (blue curve) when their input and output transducers are matched to 50Ω through optimal matching components (LMN=496 nH, and CLM=0.1 pF, see FIG. 4A having a Q equal to 75. The highlighted regions have been used to extract the average out-of-band rejection values reported in FIG. 7.

FIGS. 6A-6C show total displacement modeshapes of an MMF using the AMTL presented in FIGS. 2A-2C and two copies of the AMR presented in FIGS. 3A-3C, in FIG. 6A for a frequency (400 MHz) included in the passband of the AMRs, in FIG. 6B for a frequency (490 MHz) included in the stopband of the AMRs, and in FIG. 6C for a frequency (620 MHz) inside the deepest stopband of the AMTL.

FIG. 7 shows the average out-of-band rejection on the lefthand axis (in black) and on the righthand axis (in red) the MMF passband. The frequency ranges considered for this computation are shown in FIG. 5.

FIG. 8 shows the impact of Sc % on the MMF FBW. FEM simulated FBW for the MMF reported in FIGS. 4A-4C when considering different Sc % values and different Q values for the matching inductors.

FIGS. 9A-9L show the fabrication workflow of the MMF (9A-9H) and SEM images of the fabricated devices (9J-9L). In FIG. 9A, fabrication is started by sputtering Pt and AlScN on top of a high resistivity Si wafer (resistivity 1000-10000 ohm-cm). In FIG. 9B SiO₂ has been deposited and patterned for use as a hard mask during the formation of the release windows. FIG. 9C shows that the release windows have been etched using ICP-RIE. In FIG. 9D, another layer of SiO₂ has been patterned under the pads to decrease the parasitic capacitance due to routing. In FIG. 9E the same oxide layer has been patterned again to form the rods. In FIG. 9F Al electrodes have been deposited. In FIG. 9G Au probing pads have been deposited. In FIG. 9H, the device was released using XeF₂ isotropic etch. SEM pictures of the fabricated devices are shown in FIG. 9J for MMF, in FIG. 9K for MMF^{(PML)}, and in FIG. 9L for MMF_{(SF)}.

FIG. 10 shows measured S₂₁ responses of a fabricated AMTL and a fabricated AMR. The shaded region shows how the deepest stopband of the AMR covers the desired MMF's passband.

FIG. 11A shows measured S₂₁ of MMF, MMF^{(SF)}, and MMF^{(PML)} when their terminals are matched to 50Ω using circuit simulated matching networks having the topology depicted in FIG. 4A. FIG. 11B shows the extracted group delay of the reported MMF in FIG. 11A. The highlighted region shows the passband of the MMF. FIG. 11C shows the zoomed in measured S₂₁ responses of MMF when assuming different finite Q values for the matching network components.

FIG. 12 shows measured S₂₁ responses of the reported MMF design at different temperatures when their terminals are matched to 50Ω through circuit simulations using the matching network topology depicted in FIG. 4A.

FIG. 13 shows measured S₂₁ responses of two built MMFs with p_{AMTL}=5 μm & p_{AMR}=6 μm, and p_{AMTL}=6 μm & p_{AMR}=8 μm, with the terminals matched to 50Ω using simulated matching networks having the topology depicted in FIG. 4A.

The present application file contains drawings executed in color. Copies of the patent or patent application publication with color drawings will be provided by the United States Patent and Trademark Office upon request and payment of the necessary fee.

### DETAILED DESCRIPTION

The present technology provides microacoustic metamaterial filters (MMFs). The MMFs create a bandpass behavior by leveraging the dispersion of acoustic metamaterials, such as those made of a thin AlScN film and an array of SiO₂ rods superimposed on the film. The MMFs are configured as an acoustic metamaterial transmission line (AMTL) placed between two acoustic metamaterial reflectors (AMRs). The MMFs also include two single-electrode input and output transducers. When matched with two ideal circuit components (one inductor and one capacitor), the MMFs show a passband centered around 490 MHz and 395 MHz, a fractional bandwidth (FBW) higher than 2.5%, a maximum insertion loss of 4.9 dB, and significant out-of-band rejection reaching ˜75 dB.

The bandpass of the reported MMFs is not generated by the electrical or mechanical coupling of acoustic resonances. Instead, the bandpass originates from the passbands and stopbands of a chain of three acoustic metamaterial structures. These structures form an acoustic metamaterial transmission line (AMTL) and two acoustic metamaterial reflectors (AMRs) respectively. Two single metal strips serve as input and output transducers with a wideband frequency response. Since MMFs do not rely on resonators, they do not require high-resolution trimming or mass-loading steps to accurately tune the resonance frequency difference between various microacoustic resonant devices. These steps often involve finely controlling the thickness of a device layer, with resolutions that can be as low as a few Angstroms when building GHz filters. The acoustic bandwidth of MMFs is mostly determined by geometrical and mechanical parameters of their AM structures. MMFs necessitate external circuit components for impedance matching, in contrast to the existing microacoustic filters that often employ circuit components only to eliminate ripples within their passband.

### Principle of Operation

AMs were formed by chains of identical unit-cells. When built in suspended plates, they can inhibit the propagation of Lamb modes within certain frequency ranges often referred to as stopbands. The center frequency and width of these stopbands are determined by mechanical and geometric properties of the AM unit cell. Between adjacent stopbands, there exist one or more propagating modes that can be leveraged to guide acoustic energy across the AM structure.

MMFs are formed by an AMTL constructed between two transducers, one for the input and one for the output, which in turn lie between two AMRs. The AMRs are affixed to the surrounding substrate, while the AMTL is suspended. The combination of AMTL and AMRs creates zones of significant attenuation near the targeted filter passband. Within these zones, the propagation of longitudinal and shear waves is either blocked or heavily damped, resulting in a large out-of-band rejection although no resonator is used. The AMTL and the AMRs are formed by the same material stack, which in a preferred embodiment includes a set of silicon dioxide (SiO₂) rods deposited atop a thin AlScN film. Other suitable insulating materials can be used instead of SiO₂. The rods' longest dimension is orthogonal to the cross-section of the MMF.

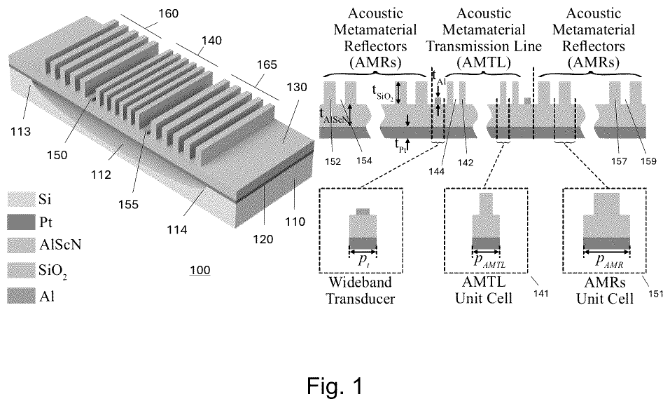

A schematic of a MMF is shown in FIG. 1. Microacoustic metamaterial filter 100 is built on substrate 110, having cavity 112, above which are suspended first electrode 120, piezoelectric layer 130, acoustic material transmission line (AMTL) 140, which is bracketed by second and third electrodes 150 and 155. Adjacent to the second and third electrodes, and opposite the sides of the AMTL, are first and second acoustic material reflectors (AMRs) 160 and 165. The AMTL includes a linear array of parallel rods 142 composed of insulating material and separated by gaps 144. A linear array of parallel rods refers to a set of repeating unit cells, each containing one rod and a portion of a separation gap on each side of the rod, along a linear dimension with the rods arranged with their longitudinal axis perpendicular to the linear dimension and the rods parallel to other rods in the array. The first and second AMRs likewise each include a linear array of parallel rods 152, 157, separated by gaps 154, 159. Note that the outside edges of the AMRs can be positioned just inside the edges 113, 114 of the cavity portion of the substrate. In an embodiment, each of the AMTL and the AMRs consists of a chain or linear array of repeating unit cells 141 (AMTL unit cell) and 151 (AMR unit cell) whose pitch is twice the width of the rods; pitches of unit cells 141 and 151 are not identical. Hereinbelow, the pitch values of the AMTL and AMR unit cells are referred to as p_{AMTL} and p_{AMR} respectively. The number of unit cells in each portion of the device (AMTL, AMRs) can vary depending on the design of the device and its intended use and specifications. A larger number of unit cells can increase the passband of the AMTL or the stopband of an AMR, but this comes at the cost of greater signal loss. In general, the number of unit cells in the AMTL and each of the AMRs can be from about 3 to about 20, or from about 4 to about 12, or from about 4 to about 8. The number of unit cells of the AMTL can differ from the number of unit cells of each of the AMRs. The input and output transducers can be formed by single aluminum (Al) strips, for example. Applying a voltage between the input transducer and ground causes transduction of a longitudinal BAW along the width of the AMTL. In a preferred embodiment, this transduction leverages the d₃₁ piezoelectric coefficient of AlScN; however, any suitable piezoelectric material can be used. The same coefficient is leveraged by the output transducer to convert the strain under the output terminal into a voltage. The AMTL and AMRs serve distinct purposes in the operation of MMFs, as described further below.

### Acoustic Metamaterial Transmission Lines

AMTLs play a central role in MMF function. Their acoustic dispersion allows the creation of complete stopbands right above the desired passband, blocking the propagation of longitudinal and shear waves along the MMF lateral direction. In these stopbands, acoustic real power cannot flow along the MMF width, restricting the electrical power transmission between input and output transducers to a minimal value that is solely determined by electrostatic feedthrough.

In order to visualize the operation of an AMTL and the origin of their stopbands, a set of Finite Element Modelling (FEM) simulations was run. Assumed was an AMTL including 15 unit cells, with a p_{AMTL} of 5 μm and a length of 80 μm. Each unit cell of the AMTL included a SiO₂ rod with a thickness of 2.2 μm and a width of 2.5 μm. The rods were located atop a 400 nm AlScN layer that had a 30% scandium doping concentration (Sc %). Also assumed were two 150 nm-thick aluminum (Al) strips as input (Port-1) and output (Port-2) transducers, like the ones used in the examples below. All the geometrical parameters considered in the simulations coincided with corresponding dimensions used in the fabricated MMF prototypes presented herein. Also assumed were two Perfectly Matched Layers (PMLs) along the lateral sides of the simulated AMTL to prevent distortions in acoustic transmission due to scattering and mode conversion at stress-free surfaces. Practically, these effects do not impact the performance of built MMFs as the devices were fully anchored along their lateral sides.

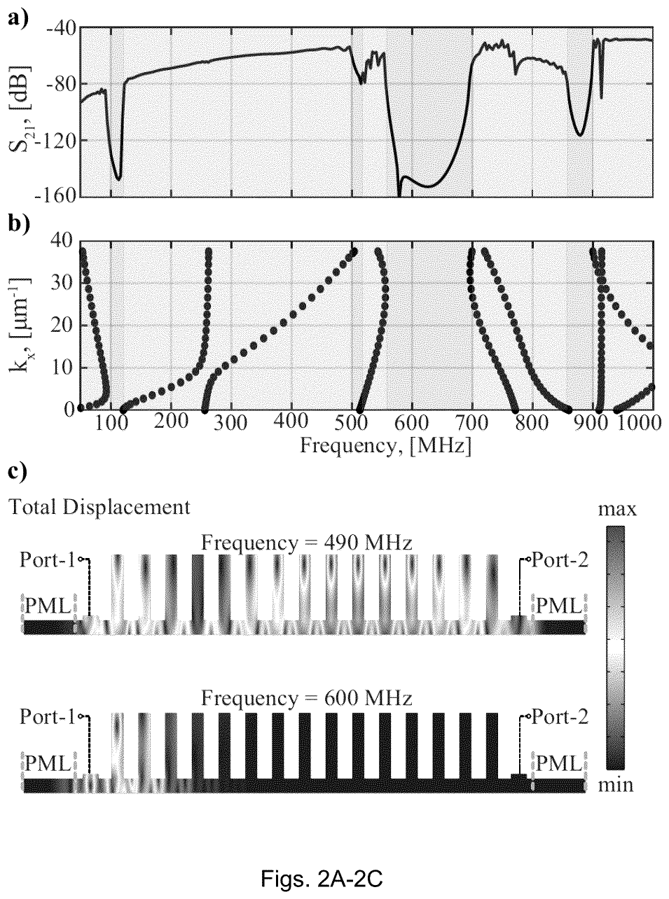

FEM simulations were started by monitoring the S₂₁ scattering parameter (FIG. 2A), which maps the transmission of electrical power from Port-1 (i.e., from the input transducer) to Port-2 (i.e., to the output transducer) when these ports are terminated with 50Ω loads. Four bands having greatly reduced S₂₁ magnitudes were found. These bands are stopbands of the AMTL structure, wherein the transmission of acoustic (thus electric) power from the input port to the output port is blocked. This was verified by running a second set of FEM simulations (FIG. 2B). In this second round of simulations, the dispersion curves of the AMTL's propagating modes with frequency were found to be included within the same frequency ranges observed in FIG. 2A. Each of the curves in FIG. 2B is drawn in terms of the corresponding mode's lateral wavevector (kₓ) vs. frequency. To run this second round of FEM simulations, Floquet boundary conditions were used at both sides of the unit cell. Also examined was the modeshape of the total displacement distribution across the cross-section of the AMTL when the device is electrically driven at various frequencies from its input terminal. FIG. 2C shows the simulated modeshape when the input frequency is within a passband (490 MHz) or a stopband (600 MHz). In the first scenario, a significant amount of acoustic energy is transmitted from the input port to the output port of the AMTL, whereas the total displacement in the second scenario is heavily dampened after passing through the first four unit cells from the input terminal.

From FIG. 2A it can be seen that S₂₁ is flat from 475 MHz to 500 MHz, while showing a large suppression for frequencies higher than 500 MHz. These two aspects can be leveraged to construct the frequency response of a bandpass filter with center frequency included between 475 MHz and 500 MHZ. The stopbands centered at 530 MHz and 650 MHz can be used to provide an out of band rejection higher than 100 dB after matching the input and output terminals to the optimal termination. The high attenuation in the AMTL stopbands is attained even though no high-Q resonator is used. This is a novel feature that prior microacoustic filters could not exploit. Nonetheless, using the unique dispersion of the AMTL to form a filter with a passband ranging from 475 MHz to 500 MHz requires creating another area of significant attenuation for frequencies below 475 MHz. This can be done by using two AMRs, as discussed in the next section.

### Acoustic Metamaterial Reflectors

The AMRs used by MMFs are utilized as frequency selective reflectors. They facilitate the lateral transmission of acoustic power from the transducers to the neighboring silicon substrate within their passbands, while impeding it within their stopbands. The AMRs must be designed in conjunction with the AMTL so that their deepest stopband covers the passband of the desired filter. This requires using a p_{AMR} value different from p_{AMTL}. In fact, the center frequency of each stopband for all the AM structures described herein can be lithographically changed by varying the pitch of their unit cells. The wide passband region of the AMRs below their most significant stopband can be used to enable a large radiation of acoustic energy into the surrounding substrate for frequencies lower than the passband of the targeted filter. This comes with a large attenuation of the acoustic power reaching the output terminal, which results in a strong reduction of the S₂₁ for frequencies below the targeted filter's passband. This allows reconstruction of the typical S₂₁ vs. frequency trend of a bandpass filter after matching the input and output terminals to the optimal termination.

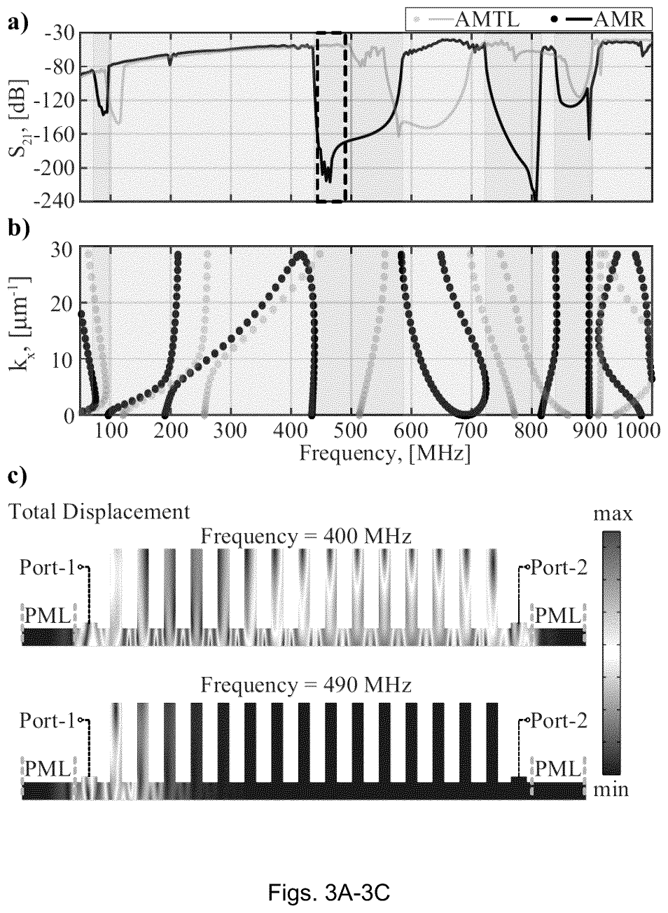

As a numerical example, FEM simulations were used to design a set of AMRs that can be connected to the AMTL structure characterized in FIGS. 2A-2C to achieve a bandpass filtering behavior from 475 MHz to 500 MHz. As done for the AMTL structure, two sets of FEM simulations were run. The first set aimed at assessing the transmission properties of an AMR at different input frequencies. For these simulations the same materials, transducers, and PML boundaries were considered as used for the characterization shown in FIGS. 2A-2C. However, a different pitch (i.e., p_{AMR}=6 μm) was used for the analyzed AM structure placed between the two terminals; it was the same pitch value used for the AMRs fabricated in the examples below. FIG. 3A shows the extracted S₂₁ vs. frequency trend for the FEM-simulated AMR structure. FIG. 3A also reintroduces the S₂₁ vs. frequency trend of the AMTL structure for an easier visualization of the key design differences between the AMRs and the AMTL. A second set of FEM simulations is shown in FIG. 3B. These simulations confirmed that the large attenuation in the S₂₁ vs. frequency trend of the AMRs originates from the presence of stopbands in their acoustic frequency response. Finally, the modeshape of the total displacement within the analyzed AMR structure is shown in FIG. 3C for two frequencies, one in a passband and one in the widest stopband. Like the AMTL described in the previous section, the analyzed AMR shows a significant total displacement for the first case and a negligible one for the second case.

### Design Considerations

Many of the characteristics of MMFs disclosed herein are understood to reflect design choices of the user, and as such their variation according to the functional and structural features described here are contemplated as within the present technology. Design choices include, but are not limited to, selection of materials, fabrication methods, absolute and relative dimensions of structures can be selected by the user based on known principles of physics, engineering, and material science. While the MMF device embodiments described herein are based on the use of metamaterials including piezoelectric materials combined with electrodes, insulators, and cavities to allow certain vibrational modes, based on known principles (see, e.g., Y. Y. Kim, Elastic Waves and Metamaterials: The Fundamentals, Springer, 2023) the same functional features can be realized using phononic crystals to form a transition line bordered by two reflectors, based on known principles (see, e.g., A. Khlif and A. Adibi, eds. Phononic Crystals, Fundamentals and Applications, Springer, 2016) which is considered within the present technology.

### Microacoustic Metamaterial Filters—Performance Bounds

The combined use of an AMTL and two AMRs enables the creation of two broad frequency regions wherein the acoustic power flowing from the input transducer of the MMF to the output transducer is significantly attenuated. The presence of these two regions reshapes the spectrum of the AMTL's acoustic transmission. As a result, MMF electrical transmission reproduces the typical behavior of a bandpass filter when the MMF terminals are properly matched to optimal terminations. The value of these terminations ultimately depends on the capacitance of the input and output transducers, Cₜ. The larger Cₜ, the closer the real part of MMFs' input impedance (Rᵢₙ) approaches 50Ω. Rᵢₙ is directly associated to the radiation resistance of MMF input and output transducers. Since MMFs do not rely on resonators for electrical matching, they require two matching networks to cancel the capacitive behavior of their input and output transducers. These matching networks can be synthesized by using networks of inductors and capacitors, arranged using a circuit topology that strictly depends on Cₜ.

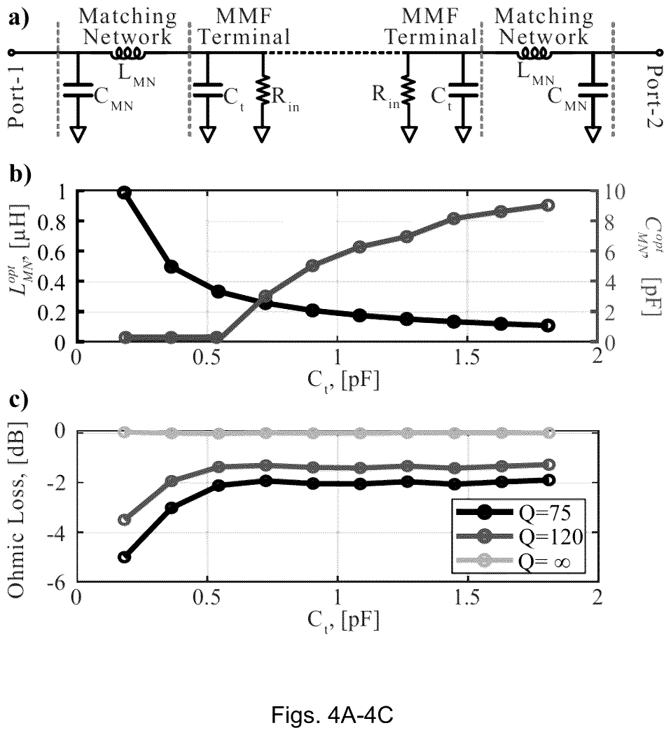

Another simulation was conducted to analyze the impact of Cₜ and the required matching network on MMF performance. The same design case was considered as in the previous two sections; specifically, the same design of filter was used, with passband extending from 475 MHz to 500 MHZ, using the AMTL and AMRs described in FIGS. 2A-2C and 3A-3C. For this case, a matching network was added to each terminal to match the input and output transducers, for a broad range of Cₜ values (see FIG. 4A). Each one of these networks relies on one inductor (L_{MN}) and one capacitor (C_{MN}). The impact of these matching networks on filter performance was evaluated through combined FEM+circuit simulations.

The plot in FIG. 4B shows the trend of the required L^{opt}_{MN} and C^{opt}_{MN} values, each vs. Cₜ, to ensure proper matching of the input and the output terminals to 50Ω. In FIG. 4C is plotted the simulated loss that MMFs experience due to ohmic dissipations in the matching networks. This loss has been computed for the same Cₜ values analyzed in FIG. 4B when assuming L_{MN} and C_{MN} to be equal to L^{opt}_{MN} and C^{opt}_{MN} respectively. All the trends shown in FIG. 4B and FIG. 4C were found by assuming a Q for all the inductors equal to 75 (the same Q of the inductors used in the AWLR filters reported in [27]), 120 (the highest Q value for ceramic inductors) or infinity (corresponding to the case of lossless matching networks). In summary, the simulation data shown in FIGS. 4A-4C suggest that larger Cₜ values allow a lower impact of the matching networks on the performance of MMFs. In other words, for large Cₜ values MMF filtering performance is mostly determined by acoustic losses in their AM structures.

Since it is desirable to have large Cₜ values, it is important to identify methods to meet this design requirement. Two approaches can be followed. One approach consists of widening the size of the input and output transducers. However, increasing the size of these transducers too much may cause undesired generation of stationary waves confined within the transducer region, causing distortions in MMF filter passband. In turn, making the transducers too long would increase the electrical loading. Another approach to increase Cₜ without risking introduction of spurious modes in the MMF passband consists of stacking multiple MMF devices with input and output terminals in parallel with each other. For the experiments described in Examples below, the latter approach has been followed.

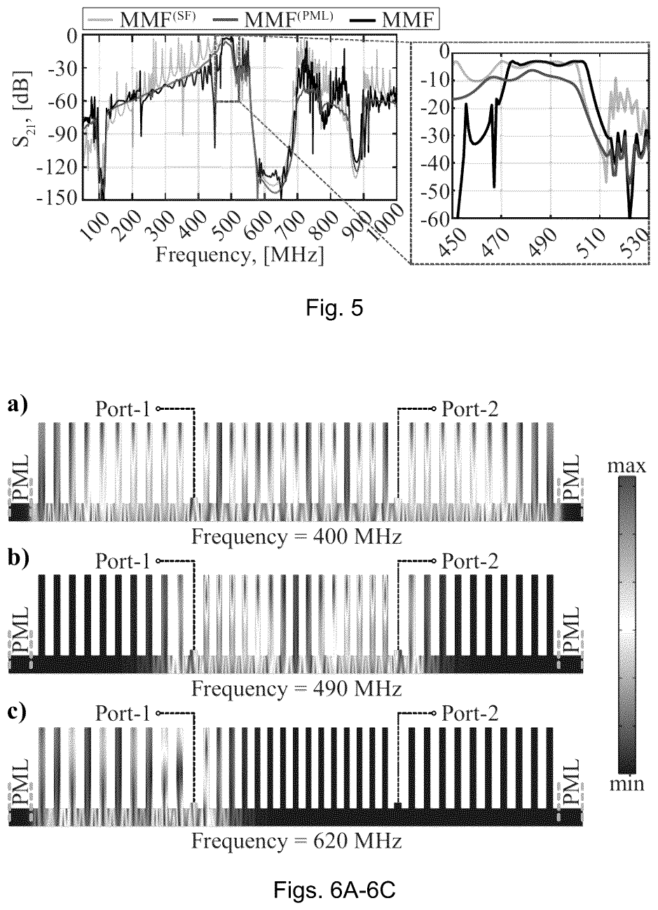

FIG. 5 presents the FEM-simulated S₂₁ response (black curve) of a MMF with two devices stacked in parallel, mirroring the experimental setup used below. This figure utilizes the same AMTL and AMRs described in FIGS. 2A-2C and 3A-3C. Also, like in the previous sections, a 30% Sc % was considered for this FEM simulation, together with a value for the total input and output capacitances (equal to 2Cₜ) of 0.36 pF, and a Q of 75 for the matching inductors. FIG. 5 also includes two other S₂₁ trends. One trend refers to the transmission of the same MMF if one replaces the AMRs with stress-free boundaries (MMF^{SF}) (blue curve). The other trend shows the S₂₁ when replacing the AMRs with perfectly matched layers (MMF^{PML}) (red curve). Evidently, the adoption of the AMRs allows the formation of the MMF passband. Also, it prevents the excitation of plate modes that are otherwise transduced when stress-free boundaries are used. At the same time, AMRs improve both the frequency selectivity and the insertion loss compared to the case where PMLs are used. It is worth noting that the biggest stopband on the right side of the MMF passband allows an out of band rejection higher than 120 dB. Such a high rejection value, attained relatively close to the MMF's passband, is hardly achievable by AWLR filters since their skirt steepness is limited by the smooth dispersion of lumped capacitors.

FIGS. 6A-6C show the total displacement mode shapes of the MMF characterized in FIG. 5 when driven at various frequencies. One driving frequency is included in the passband of the adopted AMRs (FIG. 6A), producing a large displacement across the entire device. Another frequency (FIG. 6B) is included within the passband, showing limited displacement across the width of the AMRs. The last frequency is included within the deepest stopband on the right side of the MMF's passband (FIG. 6C). Evidently, at this last analyzed frequency, the acoustic wave is fully confined in the vicinity of the input transducer.

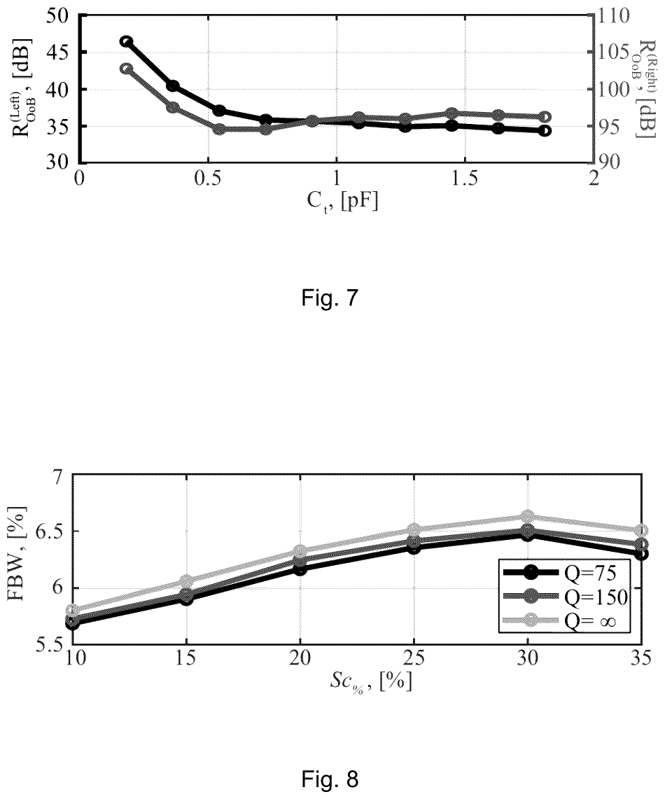

The average out-of-band rejection in FIG. 7 at both the left (R^{OoB}_{(Left)} and right (R^{OoB}₍Right) sides of the MMF's passband for varying C, values. The same matching networks were assumed as for the simulation considered in FIGS. 4A-4C.

### Impact of Scandium Doping Concentration

The dependence of the MMF 3-dB fractional bandwidth (FBW) on the level of scandium doping (Sc %) was investigated using simulations. FIG. 8 shows the trend of FBW vs. Sc % for the same case study considered in FIGS. 4A-4C. Using higher Sc % values did not significantly impact the achievable FBW. As a matter of fact, using a lower Sc % reduces the elastic modulus of the piezoelectric layer, which affects the dispersion characteristics of both the AMTL and the AMRs. Since p_{AMTL} and p_{AMR} are different, the change in their acoustic dispersion produces a sub-optimal overlap of the desired filter's passband with the stopband of the AMRs. This explains the minor variations of the simulated FBW value with different Sc % values. It is also clear that FBW does not depend significantly on the Q of the matching inductors, which also is evident from FIG. 8.

### EXAMPLES

### Example 1

### Device Fabrication

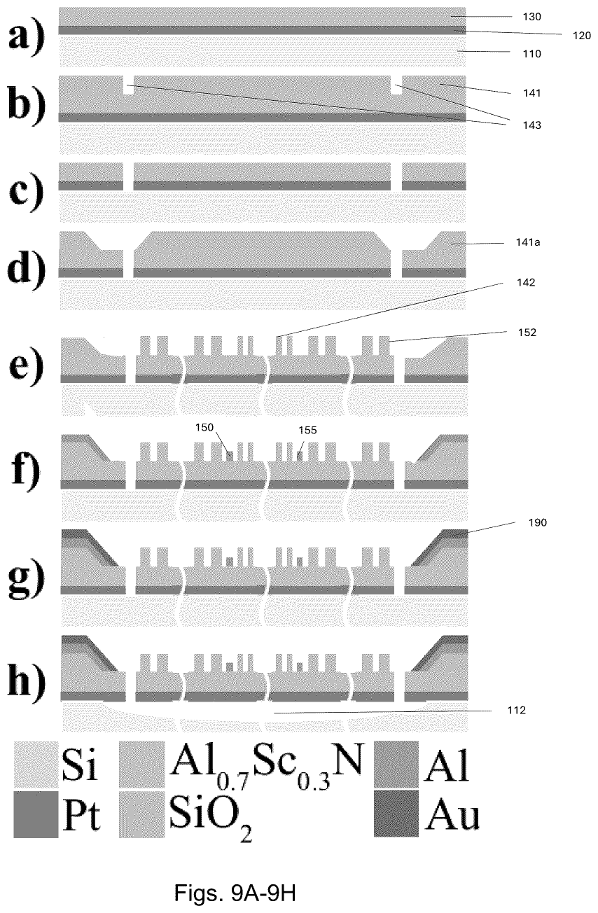

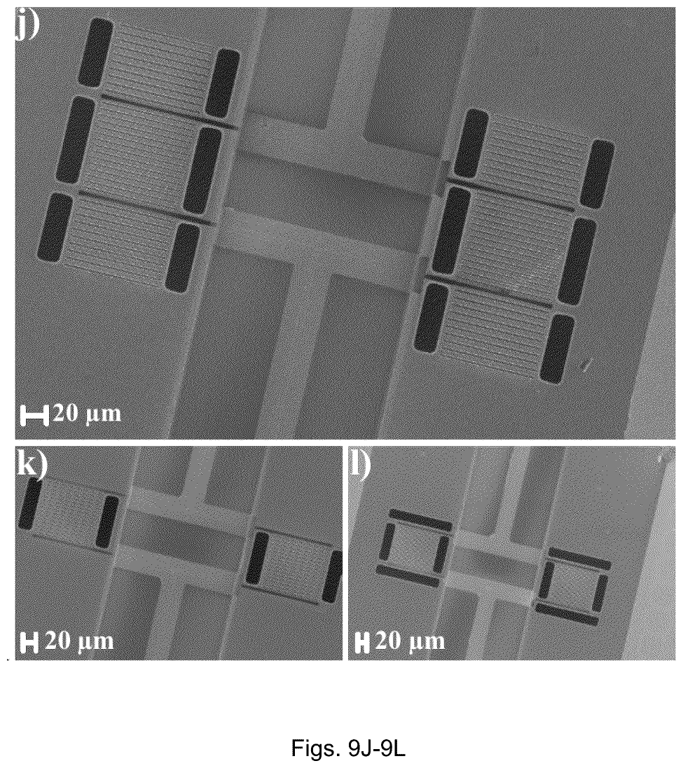

A set of MMF devices was microfabricated. Each device included the operation of an AMTL (characterized in FIGS. 2A-2C) and an AMR (characterized in FIGS. 3A-3C). A variant included the same AMTL and two copies of the same AMR (characterized in FIG. 5). The fabrication flow is described in FIG. 9. A high resistivity (HR) silicon wafer was used as a substrate 110. On top of the HR Si wafer, an 80 nm thick Pt layer 120 was sputtered, followed by a 400 nm thick AlScN thin film 130 with a Sc % value of 30% (FIG. 9A). Later, SiO₂ hard mask 141 was deposited via chemical vapor deposition (CVD) and patterned using reactive ion etching (RIE) to form release windows 143 (FIG. 9B). Subsequently, the release windows were etched using inductively coupled plasma-reactive ion etching (ICP-RIE) and the SiO₂ hard mask was stripped using hydrofluoric acid (FIG. 9C). Afterwards, a new 2.2 μm thick SiO₂ layer 141a was deposited and initially patterned to form a buffer layer. This layer allows to decrease the parasitics due to routing (FIG. 9D). Then, the same oxide layer was patterned again to form rods 142, 152 (FIG. 9E). Subsequently, Al was sputtered and patterned via lift-off to form the input and output transducers 150, 155 (FIG. 9F). Then, electrical routing and the probing pads 190 were formed by depositing and patterning a 200 nm thick gold layer (Au) (FIG. 9G). Formation of probing pads is optional and can be omitted. Probe placement, materials, configuration, and fabrication can be selected by the user. Finally, the device was released, forming cavity 112 using XeF₂ (FIG. 9H). Scanning Electron Microscopy (SEM) images of the fabricated MMF, MMF^{(PML)}, and MMF^{(SF)} devices are shown in FIGS. 9J to 9L. For all built structures, two identical devices were stacked with parallel input and output ports, in order to simplify impedance matching of input and output terminals.

### Example 2

### Device Characterization

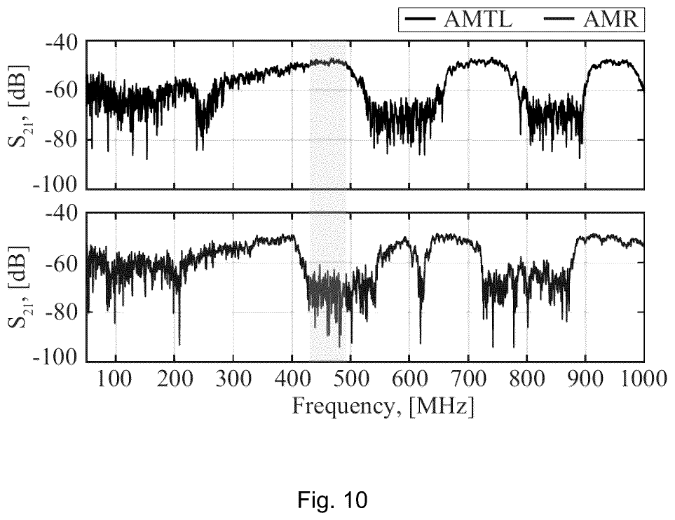

AMTL, AMR, and MMF devices built as described in Example 1 were characterized by measuring their S₂₁ trends. All the S₂₁ trends were extracted using a Vector Network Analyzer (VNA) and on-chip probes. First, the S₂₁ of the fabricated AMTL and AMR devices were tested to experimentally verify the existence of their stopbands (see FIG. 10). S₂₁ trends vs. frequency for both devices clearly demonstrate the existence of stopbands. Furthermore, the S₂₁ of the AMTL showed a low loss between 475 MHz and 500 MHZ, contrasting with the AMRs, which exhibited a large attenuation due to their operation in a stopband.

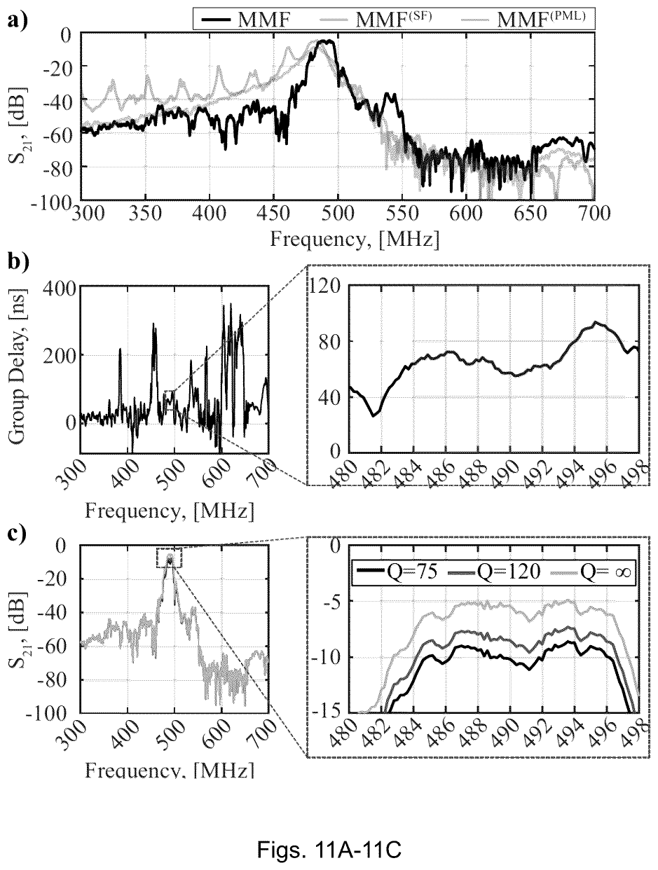

In FIG. 11A the transmission is shown of the built MMF using the same AMTL and AMR structures characterized in FIG. 10. The S₂₁ trend vs. frequency is shown for a MMF using, on behalf of the AMRs, stress-free boundaries or full connections to the silicon substrate. The S₂₁ trends reported in FIG. 11A were extracted using two identical matching networks (one per port), as shown in FIG. 4A. These networks included one ideal inductor and one ideal capacitor, with inductance (L_{LM}) and capacitance (C_{LM}) equal to 139 nH and 12 pF respectively. The S₂₁ trends reported in FIG. 11A followed the same phenomenological behavior as the corresponding simulated ones (FIG. 5). In particular, both MMF and MMF^{(SF)} showed a loss of 4.9 dB around their center frequency, while MMF^{(PML)} exhibited a loss of 9 dB due to high anchor dissipations. All these fabricated devices exhibited a similar out-of-band rejection of ˜75 dB for frequencies above the passband. Nonetheless, the MMF showed a higher out-of-band rejection for frequencies below the passband, which is enabled by AMR operation in a passband. The determined MMF skirt steepness can be quantified by the attenuation rates of 3 dB per 1 MHz on the right side of its passband and 3 dB per 1.5 MHz on the left side of its passband. The in-band group delay of the MMF characterized in FIG. 11A was extracted as 70±25 ns (FIG. 11B). The variation of the group delay inside the filter's passband is not as flat as that of the AWLR reported in [18], which is optimized for constant group delay, but it is still considerably flatter than the group delay of the ladder filters discussed in the same study. FIG. 11C shows a zoomed-in view of the S₂₁ of the MMF reported in FIG. 11A when assuming different finite Q values.

Table II compares the performance achieved by the built MMF, when assuming a set of matching components with realistic Q values (Q of 75 for inductors and Q of 400 for capacitors), with the performance attained by the indicated previously described AWLR filters. The previously described AWLR filters also utilized lumped components to create their passband, making them the most suitable current technology for comparison with MMFs. Table II lists center frequency (f_{c}), insertion loss, FBW, and rejection characteristics of all the previously AWLR filters together with those of the best MMF described herein. With regards to the rejection capabilities of all the filters listed in Table II, the magnitude of S₂₁ at frequencies that are one bandwidth away (1-BW) and two bandwidths aways (2-BW) from the edge of the passband were compared. The maximum reported rejection also is listed for all the filters listed in Table II. The present MMF outperformed all the listed AWLR filters in terms of rejection capabilities (both in 1-BW & 2-BW rejection values and the maximum achievable rejection) and FBW. The present MMF's loss, on the other hand, was higher than that of the other filters listed in the comparison table. However, loss reductions in MMFs can be obtained by increasing C_{t▪} as well as by optimizing layout and material composition used for the electrical routing, specifically at the edges of the buffer oxide layer where, currently, routing metal strips must climb a 2.2 μm step.

TABLE II
COMPARISON OF THE REPORTED MMF WITH
PREVIOUSLY REPORTED AWLR FILTERS

| | | | | Rejection [dB] | | |
|---|---|---|---|---|---|---|
| | f_{c} | Loss | FBW | 1-BW | 2-BW | |
| Filter | [MHz] | [dB] | [%] | Away | Away | Max |
| This Work | 490 | 8.6 | 2.54 | 32 | 55 | 75 |
| AWLR | 418 | 2.1 | 0.07 | 22 | 33 | 53 |
| (N = 3) [18] | | | | | | |
| AWLR | 418 | 2.4 | 0.24 | 12 | 16 | 33 |
| (N = 1), [27] | | | | | | |
| AWLR | 418 | 5.4 | 0.12 | 20 | 28 | 60 |
| (N = 2), [27] | | | | | | |
| AWLR | 417.9 | 1.25 | 0.07 | 11 | 15 | 40 |
| (N = 1) [28] | | | | | | |
| AWLR* | 417.6 | 1.15 | 0.24 | 21 | 35 | 56 |
| (N = 2) [28] | | | | | | |
| AWLR | 418 | 2 | 0.08 | 29 | 45 | 50 |
| (N = 3), [29] | | | | | | |
| AWLR | 418 | 4 | 0.03 | 24 | 30 | 70 |
| (Single- | | | | | | |
| Band), [30] | | | | | | |

N: Filter Order
*Rejection reported for 2-BW and 3-BW away because of a spurious

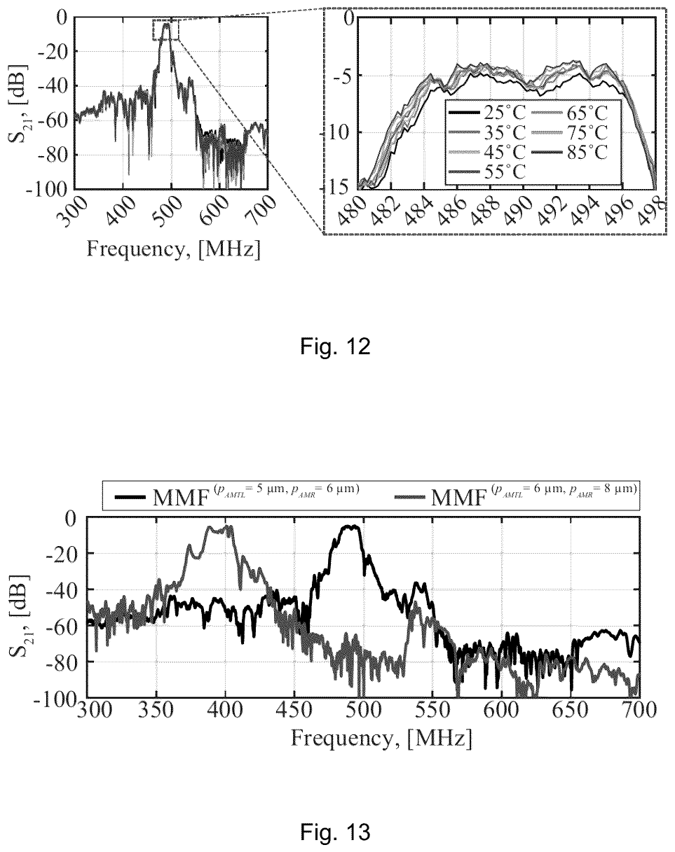

The performance of the MMF characterized in FIGS. 11A-11C was assessed at varying temperatures. During this experiment, the filter was heated on a hot plate to 85° C., with 10° C. increments, and the S₂₁ was recorded for each temperature increment. The extracted S₂₁ trends are shown in FIG. 12. As evident, the filter's passband shifts left as the temperature increase due to a reduction of the Young's modulus of the AlScN layer. This reduction is partially compensated from the selection of the SiO₂ rods, which implement a degree of passive temperature compensation [42], [43]. Based on measurements with the present device, the average Temperature Coefficient of Frequency (TCF) of the MMF center frequency is 22.2 ppm/° C.

The location of the stopbands generated by an AM structure can be tuned by changing the pitch of its unit cell. Therefore, an MMF's center frequency can be lithographically tuned by properly sizing p_{AMTL} and p_{AMR}. To illustrate this feature, the S₂₁ trend vs. frequency of another built MMF with p_{AMTL}=6 μm and p_{AMR}=8 μm was determined (see FIG. 13). This filter utilized the same matching network topology characterized in FIGS. 4A-4C, with L_{LM} and C_{LM} selected to be 201 nH and 12 pF respectively. Moreover, the S₂₁ of the MMF characterized in FIG. 11A is included in FIG. 13 to best visualize the MMFs' lithographic frequency tunability. Our second included MMF device exhibits an f_{c} value of 395 MHz, a FBW of 4.65% and a minimum loss of 5 dB.

In summary, the present technology provides novel microacoustic metamaterial filters (MMFs) including an acoustic metamaterial transmission line and reflectors. The MMFs have a steep skirt and a high out-of-band rejection. Further, since they do not employ resonating transducers, they do not need the high-resolution mass loading and trimming steps employed when building ladder filters. The center frequency of the MMF bandpass is lithographically defined. Multiple MMFs can be built on the same chip without adding fabrication steps. The MMF devices utilize the properties of metamaterials to build passband responses without requiring multiple synchronized resonators, thereby eliminating a manufacturing challenge associated with the use of resonators. The filter bandwidth is not limited by material properties, which is a huge step forward over traditional filters. Moreover, MMFs can be very small, because stopbands are used to attain large out of band rejection without requiring more filter stages, thereby saving space. Uses of the present technology include filtering for communications, such as. 5G or 6G wireless communications, and for other types of electronic filters.

U.S. Pat. No. 11,784,623 is hereby incorporated by reference in its entirety.

As used herein, “consisting essentially of” allows the inclusion of materials or steps that do not materially affect the basic and novel characteristics of the claim. Any recitation herein of the term “comprising”, particularly in a listing of components of a composition or elements of a device, constitutes inclusion of alternative embodiments in which “comprising” is replaced with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein. All examples and descriptions of specific embodiments are intended as non-limiting, and are not to be interpreted as support for or invoking means plus function or step plus function claiming. Species used to illustrate a genus are not intended to limit the genus.

### REFERENCES

1. K. Yang, C. He, J. Fang, et al., “Advanced RF filters for wireless communications,” Chip, vol. 2, no. 4, p. 100 058, 2023. DOI: 10.1016/j.chip.2023.100058.
2. R. Ruby, “A Snapshot in Time: The Future in Filters for Cell Phones,” IEEE Microwave Magazine, vol. 16, no. 7, pp. 46-59, 2015. DOI: 10.1109/MMM.2015.2429513.
3. M. Moreira, J. Bjurstrom, I. Katardjev, and V. Yantchev, “Aluminum scandium nitride thin-film bulk acoustic resonators for wide band applications,” Vacuum, vol. 86, no. 1, pp. 23-26, 2011. DOI: 10.1016/j.vacuum.2011.03.026.
4. A. Ansari, “Single Crystalline Scandium Aluminum Nitride: An Emerging Material for 5G Acoustic Filters,” in 2019 IEEE MTT-S International Wireless Symposium (IWS), Guangzhou, China: IEEE, 2019, pp. 1-3. DOI: 10.1109/IEEE-IWS.2019.8804148.
5. Y. Zou, C. Gao, J. Zhou, et al., “Aluminum scandium nitride thin-film bulk acoustic resonators for 5G wideband applications,” Microsystems & Nanoengineering, vol. 8, no. 1, pp. 1-7, 2022. DOI: 10.1038/s41378-022-00457-0.
6. L. Chen, C. Liu, M. Li, et al., “Scandium-Doped Aluminum Nitride for Acoustic Wave Resonators, Filters, and Ferroelectric Memory Applications,” ACS Applied Electronic Materials, vol. 5, no. 2, pp. 612-622, 2023. DOI: 10.1021/acsaelm.2c01409.
7. A. Lozzi, E. Ting-Ta Yen, P. Muralt, and L. G. Villanueva, “Al 0.83 Sc 0.17 N Contour-Mode Resonators With Electromechanical Coupling in Excess of 4.5%,” IEEE Transactions on Ultrasonics, Ferroelectrics, and Frequency Control, vol. 66, no. 1, pp. 146-153, 2019. DOI: 10.1109/TUFFC.2018.2882073.
8. G. Esteves, T. R. Young, Z. Tang, et al., “AI0.68Sc0.32N Lamb wave resonators with electromechanical coupling coefficients near 10.28%,” Applied Physics Letters, vol. 118, no. 17, p. 171 902, 2021. DOI: 10.1063/5.0047647.

1 9. L. Colombo, A. Kochhar, C. Xu, G. Piazza, S. Mishin, and Y. Oshmyansky, “Investigation of 20% Scandium-doped Aluminum Nitride Films for MEMS Laterally Vibrating Resonators”.
10. Z. Lu and Y. Dong, “SAW Filter with High Out-of-Band Rejection Using Improved Grounding Method,” in 2023 IEEE MTT-S International Wireless Symposium (IWS), Qingdao, China: IEEE, 2023, pp. 1-3. DOI: 10.1109/IWS58240.2023.10222703.
11. O. L. Balysheva, “SAW Filters for Mobile Communications: Achievements and Prospects,” in 2019 Wave Electronics and its Application in Information and Telecommunication Systems (WECONF), Saint-Petersburg, Russia: IEEE, 2019, pp. 1-4. DOI: 10.1109/WECONF.2019.8840661.
12. J. Liang, H. Zhang, D. Zhang, H. Zhang, and W. Pang, “500-terminated ALN MEMS filters based on lamb wave resonators,” in 2015 Transducers—2015 18th International Conference on Solid-State Sensors, Actuators and Microsystems (TRANSDUCERS), Anchorage, AK, USA: IEEE, 2015, pp. 1973-1976. DOI: 10.1109/TRANSDUCERS.2015. 7181340.
13. C. Cassella, G. Chen, Z. Qian, G. Hummel, and M. Rinaldi, “RF Passive Components Based on Aluminum Nitride Cross-Sectional Lamé-Mode MEMS Resonators,” IEEE Transactions on Electron Devices, vol. 64, no. 1, pp. 237-243, 2017. DOI: 10.1109/TED.2016.2621660.
14. G. Chen, C. Cassella, T. Wu, and M. Rinaldi, “Single-chip multi-frequency wideband filters based on aluminum nitride cross-sectional Lamé mode resonators with thick and apodized electrodes,” in 2018 IEEE Micro Electro Mechanical Systems (MEMS), Belfast: IEEE, 2018, pp. 775-778. DOI: 10.1109/MEMSYS.2018.8346670.
15. Z. Schaffer and G. Piazza, “Investigation of Damping and Ladder Filter Synthesis for 3 GHz 20% Scandium-Doped Aluminum Nitride Cross-Sectional Lame Mode Resonators,” in 2020 IEEE International Ultrasonics Symposium (IUS), Las Vegas, NV, USA: IEEE, 2020, pp. 1-4. DOI: 10.1109/IUS46767.2020.9251790.
16. S. Nam, W. Peng, P. Wang, D. Wang, Z. Mi, and A. Mortazawi, “A mm-Wave Trilayer AlN/ScAlN/AlN Higher Order Mode FBAR,” IEEE Microwave and Wireless Technology Letters, vol. 33, no. 6, pp. 803-806, 2023. DOI: 10.1109/LMWT.2023.3271865.
17. V. Chulukhadze, K. Huynh, J. Kramer, et al., “Frequency Scaling Millimeter Wave Acoustic Resonators using Ion Beam Trimmed Lithium Niobate,” in 2023 Joint Conference of the European Frequency and Time Forum and IEEE International Frequency Control Symposium (EFTF/IFCS), Toyama, Japan: IEEE, 2023, pp. 1-4. DOI: 10.1109/EFTF/IFCS57587.2023.10272038.
18. D. Psychogiou, R. Gómez-Garda, and D. Peroulis, “RF design of acoustic-wave-lumped-element-resonator-(AWLR)-based bandpass filters with constant in-band group delay,” in 2017 IEEE MTT-S International Microwave Symposium (IMS), 2017, pp. 1472-1475. DOI: 10.1109/MWSYM.2017.8058899.
19. M. Rinaldi, C. Zuniga, C. Zuo, and G. Piazza, “Ultra-thin Super High Frequency two-port ALN contour-mode resonators and filters,” in TRANSDUCERS 2009—2009 International Solid-State Sensors, Actuators and Microsystems Conference, Denver, CO, USA: IEEE, 2009, pp. 577-580. DOI: 10.1109/SENSOR.2009.5285390.
20. C.-M. Lin, Y.-Y. Chen, V. V. Felmetsge, D. G. Senesky, and A. P. Pisano, “Two-port filters and resonators on AlN/3C—SiC plates utilizing high-order Lamb wave modes,” in 2013 IEEE 26th International Conference on Micro Electro Mechanical Systems (MEMS), Taipei, Taiwan: IEEE, 2013, pp. 789-792. DOI: 10.1109/MEMSYS.2013. 6474361.
21. J. Meltaus and T. Pensala, “Laterally coupled BAW filter using two acoustic modes,” in 2013 IEEE International Ultrasonics Symposium (IUS), Prague, Czech Republic: IEEE, 2013, pp. 232-235. DOI: 10.1109/ULTSYM.2013.0060.
22. T. Pensala, T. Makkonen, J. Dekker, and M. Ylilammi, “Laterally Acoustically Coupled BAW Filters at 3.6 GHZ,” in 2018 IEEE International Ultrasonics Symposium (IUS), Kobe: IEEE, 2018, pp. 1-4. DOI: 10.1109/ULTSYM.2018.8579900.
23. G. Fattinger, R. Aigner, and W. Nessler, “Coupled bulk acoustic wave resonator filters: Key technology for single-to-balanced RF filters,” in 2004 IEEE MTT-S International Microwave Symposium Digest (IEEE Cat. No.04CH37535), vol. 2, Forth Worth, TX, USA: IEEE, 2004, pp. 927-929. DOI: 10.1109/MWSYM.2004.1339126.
24. K. Lakin, “Coupled resonator filters,” in 2002 IEEE Ultrasonics Symposium, 2002. Proceedings, Munich, Germany: IEEE, 2002, pp. 901-908. DOI: 10.1109/ULTSYM.2002.1193543.
25. A. Shirakawa, J.-M. Pham, P. Jarry, and E. Kerherve, “Bulk acoustic wave coupled resonator filters synthesis methodology,” in 2005 European Microwave Conference, Paris, France: IEEE, 2005, 4 pp. DOI: 10.1109/EUMC.2005.1608915.
26. A. A. Shirakawa, R. Thalhammer, T. Jamneala, and U. B. Koelle, “Bulk acoustic wave-coupled resonator filters: Concept, design, and application,” International Journal of RF and Microwave Computer-Aided Engineering, vol. 21, no. 5, pp. 477-485, 2011. DOI: 10.1002/mmce.20552.
27. D. Psychogiou, R. Gómez-Garcia, and D. Peroulis, “Coupling-Matrix-Based Design of High-Q Bandpass Filters Using Acoustic-Wave Lumped-Element Resonator (AWLR) Modules,” IEEE Transactions on Microwave Theory and Techniques, vol. 63, no. 12, pp. 4319-4328, 2015. DOI: 10.1109/TMTT.2015.2494597.
28. D. Psychogiou, R. Gómez-Garcia, R. Loeches-Sánchez, and D. Peroulis, “Hybrid Acoustic-Wave-Lumped-Element Resonators (AWLRs) for High-Q Bandpass Filters With Quasi-Elliptic Frequency Response,” IEEE Transactions on Microwave Theory and Techniques, vol. 63, no. 7, pp. 2233-2244, 2015. DOI: 10.1109/TMTT.2015.2438894.
29. D. Psychogiou, R. Gómez-Garci\acute{ }a, and D. Peroulis, “Single and Multi-band Acoustic-Wave-Lumped-Element-Resonator (AWLR) Bandpass Filters With Reconfigurable Transfer Function,” IEEE Transactions on Microwave Theory and Techniques, vol. 64, no. 12, pp. 4394-4404, 2016. DOI: 10.1109/TMTT.2016.2617884.
30. N. S. Luhrs, D. J. Simpson, and D. Psychogiou, “Multiband Acoustic-Wave-Lumped-Element Resonator-Based Bandpass-to-Bandstop Filters,” IEEE Microwave and Wireless Components Letters, vol. 29, no. 4, pp. 261-263, 2019. DOI: 10.1109/LMWC.2019.2901199.
31. S. A. Cummer, J. Christensen, and A. Alu\grave{ }, “Controlling sound with acoustic metamaterials,” Nature Reviews Materials, vol. 1, no. 3, pp. 1-13, 2016. DOI: 10.1038/natrevmats.2016.1.
32. N. Fang, D. Xi, J. Xu, et al., “Ultrasonic metamaterials with negative modulus,” Nature Materials, vol. 5, no. 6, pp. 452-456, 2006. DOI: 10.1038/nmat1644.
33. Z. Yang, J. Mei, M. Yang, N. H. Chan, and P. Sheng, “Membrane-Type Acoustic Metamaterial with Negative Dynamic Mass,” Physical Review Letters, vol. 101, no. 20, p. 204 301, 2008. DOI: 10.1103/PhysRevLett.101.204301.
34. X. Zhu, B. Liang, W. Kan, X. Zou, and J. Cheng, “Acoustic Cloaking by a Superlens with Single-Negative Materials,” Physical Review Letters, vol. 106, no. 1, p. 014 301, 2011. DOI: 10.1103/PhysRevLett. 106.014301.
35. M. D. Guild, M. R. Haberman, and A. Alu\grave{ }, “Plasmonic-type acoustic cloak made of a bilaminate shell,” Physical Review B, vol. 86, no. 10, p. 104 302, 2012. DOI: 10.1103/PhysRevB.86.104302.
36. R. Ardito, C. Comi, V. Zega, and A. Corigliano, “Metamaterials and MEMS (MetaMEMS): A promising trend in Microsystems technology,” in 2023 24th International Conference on Thermal, Mechanical and Multi-Physics Simulation and Experiments in Microelectronics and Microsystems (EuroSimE), 2023, pp. 1-4. DOI: 10.1109/EuroSimE56861.2023.10100824.
37. J. Li, L. Fok, X. Yin, G. Bartal, and X. Zhang, “Experimental demonstration of an acoustic magnifying hyperlens,” Nature Materials, vol. 8, no. 12, pp. 931-934, 2009. DOI: 10.1038/nmat2561.
38. C. M. Park, J. J. Park, S. H. Lee, Y. M. Seo, C. K. Kim, and S. H. Lee, “Amplification of Acoustic Evanescent Waves Using Metamaterial Slabs,” Physical Review Letters, vol. 107, no. 19, p. 194 301, 2011. DOI: 10.1103/PhysRevLett.107.194301.
39. X. Zhao, L. Colombo, and C. Cassella, “Aluminum nitride two-dimensional-resonant-rods,” Applied Physics Letters, vol. 116, no. 14, p. 143 504, 2020. DOI: 10.1063/5.0005203.
40. X. Zhao, O. Kaya, M. Pirro, et al., “A 5.3 GHZ Al 0.76 Sc 0.24 N Two-Dimensional Resonant Rods Resonator With a kt2 of 23.9%,” Journal of Microelectromechanical Systems, vol. 31, no. 4, pp. 561-570, 2022. DOI: 10.1109/JMEMS.2022.3178978.
41. X. Zhao, O. Kaya, M. Pirro, P. Simeoni, J. Segovia-Fernandez, and C. Cassella, “Extending the Linearity of AlScN Contour-Mode Resonators Through Acoustic Metamaterials-Based Reflectors,” IEEE Transactions on Ultrasonics, Ferroelectrics, and Frequency Control, vol. 70, no. 10, pp. 1229-1238, 2023. DOI: 10.1109/TUFFC.2023. 3245809.
42. C.-M. Lin, T.-T. Yen, Y.-J. Lai, et al., “Experimental study of temperature-compensated aluminum nitride Lamb wave resonators,” in 2009 IEEE International Frequency Control Symposium Joint with the 22nd European Frequency and Time forum, 2009, pp. 5-9. DOI: 10.1109/FREQ.2009.5168132.
43. C.-M. Lin, T.-T. Yen, V. V. Felmetsger, M. A. Hopcroft, J. H. Kuypers, and A. P. Pisano, “Thermal compensation for aluminum nitride Lamb wave resonators operating at high temperature,” in 2010 IEEE International Frequency Control Symposium, 2010, pp. 14-18. DOI: 10. 1109/FREQ.2010.5556381.

What is claimed is:

1. A microacoustic metamaterial bandpass filter (MMF) comprising:
a substrate;
a first electrode configured as a layer of a first conductive material disposed on the substrate and extending over a cavity portion of the substrate;
a piezoelectric material layer disposed on the first electrode opposite the substrate and cavity portion of the substrate;
an acoustic metamaterial transmission line (AMTL), the AMTL comprising a plurality of AMTL rods disposed on the piezoelectric material layer above the cavity portion, the AMTL rods comprising an electrically insulating material and configured as a parallel linear array of the AMTL rods spaced apart by gaps along a longitudinal dimension of the AMTL rods;
an input transducer comprising a second electrode disposed along a first side of the AMTL;
an output transducer comprising a third electrode disposed along a second side of the AMTL opposite the first side of the AMTL;
a first acoustic metamaterial reflector (AMR) having first and second sides, the first side disposed along the input transducer and opposite the first side of the AMTL, the first AMR comprising a plurality of first AMR rods disposed on the piezoelectric material layer above the cavity portion, the first AMR rods comprising an electrically insulating material and configured as a parallel linear array of the first AMR rods spaced apart by gaps along a longitudinal dimension of the first AMR rods; and
a second AMR having first and second sides, the first side disposed along the output transducer and opposite the second side of the AMTL, the second AMR comprising a plurality of second AMR rods disposed on the piezoelectric material layer above the cavity portion, the second AMR rods comprising or consisting of an electrically insulating material and configured as a parallel array of the second AMR rods spaced apart by gaps along a longitudinal dimension of the second AMR rods.

2. The MMF of claim 1, wherein the AMTL comprises a plurality of unit cells, each unit cell consisting of a single rod, a portion of the piezoelectric layer on which the rod is disposed, and a portion of the first electrode on which the piezoelectric layer is disposed, wherein each unit cell has a pitch p_{AMTL} which extends from a midpoint of the gap on one side of the rod to a midpoint of the gap on the other side of the rod, and optionally wherein p_{AMTL} is constant for all unit cells of the AMTL.

3. The MMF of claim 1, wherein the first AMR comprises a plurality of unit cells, each unit cell consisting of a single rod, a portion of the piezoelectric layer on which the rod is disposed, and a portion of the first electrode on which the piezoelectric layer is disposed, wherein each unit cell has a pitch p_{AMR1} which extends from a midpoint of the gap on one side of the rod to a midpoint of the gap on the other side of the rod, and optionally wherein p_{AMR1} is constant for all unit cells of the first AMR.

4. The MMF of claim 1, wherein the second AMR comprises a plurality of unit cells, each unit cell consisting of a single rod, the piezoelectric layer on which the rod is disposed, and the first electrode on which the piezoelectric layer is disposed, wherein each unit cell has a pitch p_{AMR2} which extends from a midpoint of the gap on one side of the rod to a midpoint of the gap on the other side of the rod, and optionally wherein p_{AMR2} is constant for all unit cells of the second AMR.

5. The MMF of claim 4, wherein for p_{AMTL}, p_{AMR1}, and/or p_{AMR2} the pitch is equal to 1.2 to 5 times a width of the corresponding rod.

6. The MMF of claim 2 wherein the AMTL has a passband having a center frequency, and wherein the passband center frequency is determined by p_{AMTL}.

7. The MMF of claim 4, wherein each of the AMRs has a stopband having a center frequency, and wherein the stopband center frequency of the first AMR is determined by p_{AMR1}, and wherein the stopband center frequency of the second AMR is determined by p_{AMR2}.

8. The MMF of claim 1, wherein applying an input voltage at the first electrode and ground at the second electrode causes transduction of a longitudinal bulk acoustic wave along a width of the AMTL, and wherein the bulk acoustic wave causes an output voltage relative to ground to be produced at the third electrode.

9. The MMF of claim 1, further comprising matching networks at each of the input transducer and the output transducer.

10. The MMF of claim 1, wherein the passband is in the radio frequency range or in the microwave frequency range.

11. The MMF of claim 1, wherein the MMF does not contain any resonators.

12. The MMF of claim 1, wherein the piezoelectric material comprises scandium-doped aluminum nitride.

13. The MMF of claim 1 having one or more of a fractional bandwidth of at least about 2.5%, an insertion loss of less than about 5 dB, an in-band group delay in the range of 70±25 ns, and a temperature coefficient of frequency of about 22 ppm/° C.

14. A filter device comprising two or more identical or nonidentical MMFs of claim 1 linked in parallel through their input and output terminals.

15. A circuit, chip, or electronic device comprising one or more MMFs of claim 1.

16. The MMF of claim 1 which is embodied in an RF front end of a wireless communication device.

17. A method of filtering a radio frequency or microwave frequency signal in an electronic circuit, the method comprising the steps of:
(a) providing the MMF of claim 1;
(b) applying said signal at the input terminal of the MMF; and
(c) receiving a filtered signal at the output terminal of the MMF.

18. A method of fabricating a microacoustic metamaterial filter, the method comprising the steps of:
(a) providing a planar insulating substrate;
(b) depositing a layer of conductive material on a surface of the substrate to form a first electrode;
(c) depositing a layer of piezoelectric material on the first electrode opposite the substrate;
(d) depositing a layer of insulating material on the layer of piezoelectric material opposite the first electrode;
(e) patterning the insulating material to form a first linear array of parallel rods separated by gaps and configured as a transmission line, and second and third linear arrays of parallel rods separated by gaps, the second and third linear arrays configured as first and second reflectors, one reflector disposed on each end of the transmission line;
(e) depositing a layer of conductive material to form second and third electrodes, wherein each of the second and third electrodes lies in a gap between a side of the transmission line and a side of the first or second reflector, the second and third electrodes each deposited onto an exposed portion of the piezoelectric material in said gaps; and
(f) etching a cavity in the substrate beneath a portion of the first electrode, the cavity underlying the transmission line and first and second reflectors.

19. The method of claim 18, wherein the planar insulating substrate comprises high resistivity silicon; and/or wherein the first electrode comprises platinum; and/or wherein the piezoelectric material comprises scandium-doped aluminum nitride; and/or wherein the rods comprise silicon dioxide; and/or wherein the second and third electrodes comprise aluminum.

20. The method of claim 18, wherein the first electrode has a thickness from about 50 nm to about 350 nm, and/or wherein the piezoelectric material layer has a thickness from about 200 nm to about 2.5 μm, and/or wherein the second and third electrodes have a thickness from about 50 nm to about 300 nm, and/or wherein the cavity has a height from about 40 μm to about 500 μm.
